(19) United States
(12) Patent Application Publication
(10) Pub. No.: US 2015/0069509 A1
(43) Pub. Date: Mar. 12, 2015

(54) SEMICONDUCTOR DEVICE

(71) Applicant: SK hynix Inc., Gyeonggi-do (KR)

(72) Inventors: Sang-Hyun LEE, Gyeonggi-do (KR); Dae-Hoon KIM, Gyeonggi-do (KR); Se-Kyung OH, Gyeonggi-do (KR); Soon-Yeol PARK, Gyeonggi-do (KR)

(73) Assignee: SK hynix Inc., Gyeonggi-do (KR)

(21) Appl. No.: 14/137,135

(22) Filed: Dec. 20, 2013

(30) Foreign Application Priority Data
Sep. 6, 2013 (KR) 10-2013-0107434

(51) Int. Cl. H01L 29/78; H01L 29/06

(52) U.S. Cl. CPC H01L 29/7816; H01L 29/06
USPC 257/343; 257/655

(57) ABSTRACT

A semiconductor device includes a substrate having a supporting substrate, wherein a first epitaxial layer and a second epitaxial are sequentially stacked, an isolation region including a first buried impurity region of a second conductivity type and a second buried impurity region of the second conductivity type wherein the first buried impurity region is formed from the supporting substrate to the first epitaxial layer, and the second buried impurity region is formed from the first epitaxial layer to the second epitaxial layer and is in contact with an edge of the first buried impurity region, a third buried impurity region of a first conductivity type formed from the first epitaxial layer to the second epitaxial layer, located in the second buried impurity region and overlapped with the first buried impurity region, and a transistor formed over the second epitaxial layer and overlapped with the third buried impurity region.

### CROSS-REFERENCE TO RELATED APPLICATIONS

The present application claims priority of Korean Patent Application No. 10-2013-0107434, filed on Sep. 6, 2013, which is incorporated herein by reference in its entirety.

### BACKGROUND

1. Field

Exemplary embodiments of the present invention relate to a semiconductor device and a method of fabricating the same, and more particularly, to a high voltage isolated transistor and a method for fabricating the same.

2. Description of the Related Art

A high voltage transistor has a high power gain and a simple gate driving circuit compared with a general bipolar transistor. Additionally, delay time is not caused by accumulation or recombination due to a minority carrier in a turnoff operation of the high voltage transistor. Thus, the high voltage transistor may be widely used in various power devices such as a driving integrated circuit (IC), a power converter, a motor controller and a power supply unit for a vehicle.

A double diffused metal oxide semiconductor field effect transistor (DMOS) using a double diffusion technology such as a lateral double diffused MOSFET (LDMOS) may be used as the high voltage transistor.

### SUMMARY

Various embodiments of the present invention are directed to a semiconductor that may have an increased breakdown voltage and a method for fabricating the same.

In accordance with an embodiment of the present invention, a semiconductor device includes a substrate having a supporting substrate, wherein a first epitaxial layer and a second epitaxial are sequentially stacked, an isolation region including a first buried impurity region of a second conductivity type and a second buried impurity region of the second conductivity type, wherein the first buried impurity region is formed from the supporting substrate to the first epitaxial layer, and the second buried impurity region is formed from the first epitaxial layer to the second epitaxial layer and is in contact with an edge of the first buried impurity region, a third buried impurity region of a first conductivity type formed from the first epitaxial layer to the second epitaxial layer, located in the second buried impurity region and overlapped with the first buried impurity region, and a transistor formed over the second epitaxial layer and overlapped with the third buried impurity region.

In accordance with another embodiment of the present invention, a semiconductor device includes a substrate having a supporting substrate, wherein a first epitaxial layer and a second epitaxial are sequentially stacked, a transistor including a body region of a first conductivity, a drift region of a second conductivity and a gate, wherein the body region is formed over the second epitaxial layer, wherein the drift region is formed over the second epitaxial layer and at both sides of the body region, and the gate is partially overlapped with the body region and the drift region, a third buried impurity region of the first conductivity type formed from the first epitaxial layer to the second epitaxial layer, and formed under the body region and the drift region, and an isolation region including a first buried impurity region of the second conductivity type and a second buried impurity region of the second conductivity type, wherein the first buried impurity region wraps a bottom of a structure including the body region and the drift region and the third buried impurity region, and the second buried impurity region surrounds a side of the structure.

In accordance with still embodiment of the present invention, a method for fabricating a semiconductor device includes performing an ion implantation process over a portion of a supporting substrate with a first impurity of a second conductivity type, forming a first epitaxial layer over the supporting substrate and simultaneously forming a first buried impurity region of the second conductivity type from the supporting substrate to the first epitaxial layer by activating the first impurity, performing the ion implantation process over a portion of the first epitaxial layer corresponding to an edge of the first buried impurity region with a second impurity of the second conductivity type, and performing the ion implantation process over a portion of the first epitaxial layer corresponding to the first buried impurity region with a third impurity of a first conductivity type, forming a second epitaxial layer over the first epitaxial layer and simultaneously forming a second buried impurity region of the second conductivity type from the first epitaxial layer to the second epitaxial layer and a third buried impurity region of the first conductivity type by activating the second impurity and the third impurity, and forming a transistor overlapped with the first buried impurity region and the third buried impurity region over the second epitaxial layer.

The third buried impurity region may include a shape selected from a group including a flat panel shape, a ring shape, a concentric circular shape, a slit shape, a shape having a plurality of polygons and a checkered shape.

Impurity doping concentration of the third buried impurity region may be a constant or increases from center to edge in the third buried impurity region.

Impurity doping concentration of the first buried impurity region may be a constant or decreases from center to edge in the first buried impurity region.

The second buried impurity region may have a ring shape surrounding the third buried impurity region, and the second buried impurity region may be arranged apart from the third buried impurity region by a predetermined distance.

The first conductivity type may be complementary to the second conductivity type.

### BRIEF DESCRIPTION OF THE DRAWINGS

FIG. 1A is a plan view illustrating a high voltage isolated transistor in accordance with an embodiment of the present invention.

FIG. 1B illustrates a cross-sectional view of the high voltage isolated transistor taken along I-I′ line of FIG. 1A in accordance with an embodiment of the present invention.

FIG. 2A to 2D are plan views illustrating modifications of a third buried impurity region in accordance with an embodiment of the present invention;

FIG. 3 is a diagram illustrating a doping profile of a third buried impurity region in accordance with an embodiment of the present invention.

FIG. 4 is a diagram illustrating a doping profile of a first buried impurity region in accordance with an embodiment of the present invention.

FIGS. 5A to 5D are cross-sectional views illustrating a method for fabricating a semiconductor device in accordance with an embodiment of the present invention taken along line of FIG. 1A.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. It is also noted that in this specification, “connected/coupled” refers to one component not only directly coupling another component but also indirectly coupling another component through an intermediate component. In addition, a singular form may include a plural form as long as it is not specifically mentioned in a sentence.

Embodiment of the present invention described below provides a high voltage transistor and a method for fabricating the same. Before describing the high voltage transistor according to an exemplary embodiment of the present invention, the general high voltage transistor is formed over an epitaxial layer that is doped with impurities on a supporting substrate or bulk substrate. To increase the breakdown voltage of the high voltage transistor, the epitaxial layer is thick and the impurity doping concentration of the epitaxial layer is low. However, since the epitaxial layer is thick and the impurity doping concentration of the epitaxial layer is low, parasitic devices such as parasitic bipolar transistors may cause a decrease of a breakdown voltage, and may be easily activated. The high voltage transistor when applied to an inductive load driving system, such as an antenna or a solenoid, cannot ensure required breakdown voltage characteristics due to an excessive effect of the parasitic devices. A solution to this concern is introducing high voltage isolated transistors having a bottom and sides wrapped by an impurity region. However, ensuring the breakdown voltage of 40V or more is difficult.

Hereinafter, an embodiment of the present invention described below provides a high voltage isolated transistor having an increased breakdown voltage and a method for fabricating the same. The high voltage isolated transistor includes a substrate having a plurality of epitaxial layers stacked over a supporting substrate, a buried impurity region for alleviating an electric field, and an isolation region surrounding a bottom and sides of a structure having the transistor and the buried impurity region. In the embodiment of the present invention, a lateral double diffused MOSFET (LDMOS) using a double diffusion technology is exemplary described.

In the following description, a first conductivity type or a second conductivity type represents a conductivity type complementary to each other. That is, when the first conductivity type is P-type then the second conductivity type is N-type, and when the first conductivity type is N-type then the second conductivity type is P-type. In the following description, the first conductivity type and the second conductivity type are described as N-type and P-type, respectively.

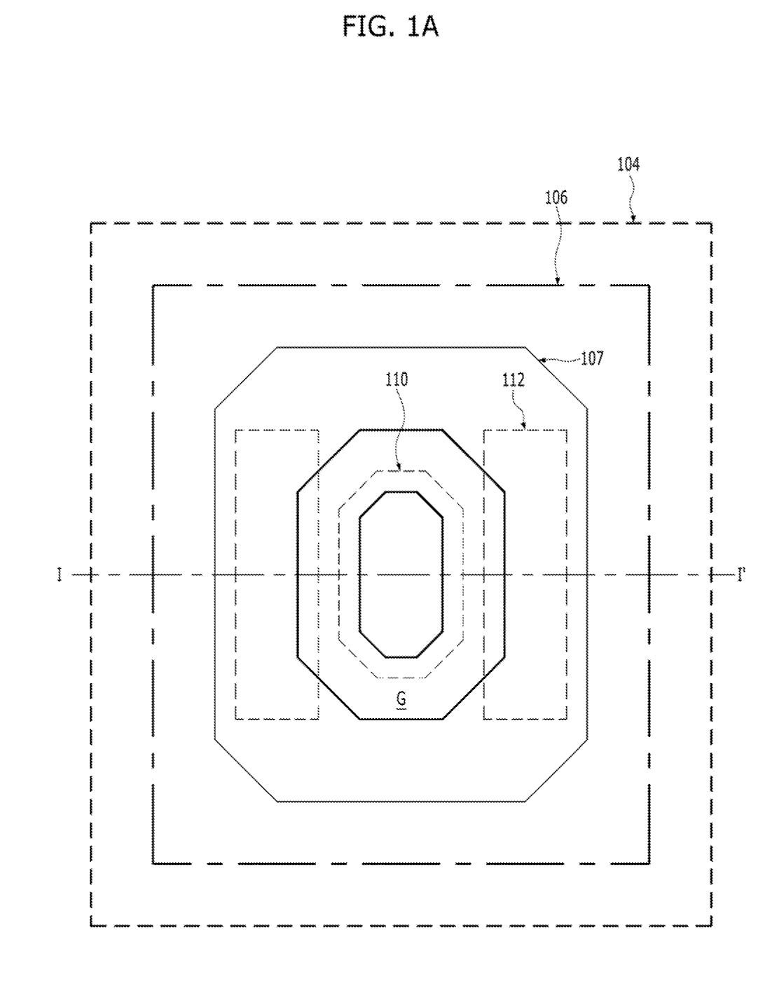

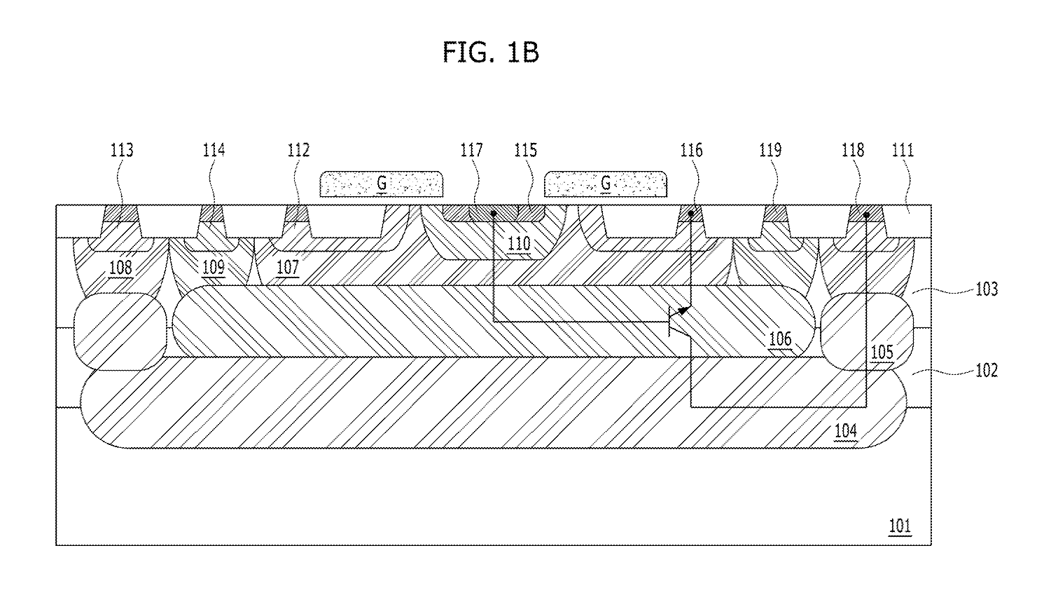

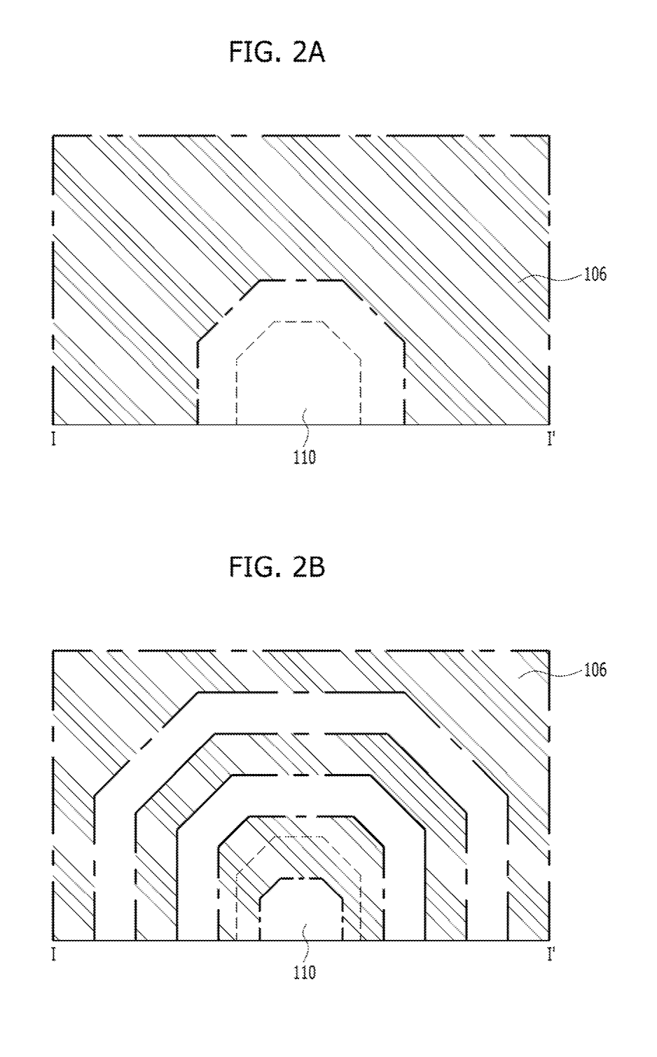

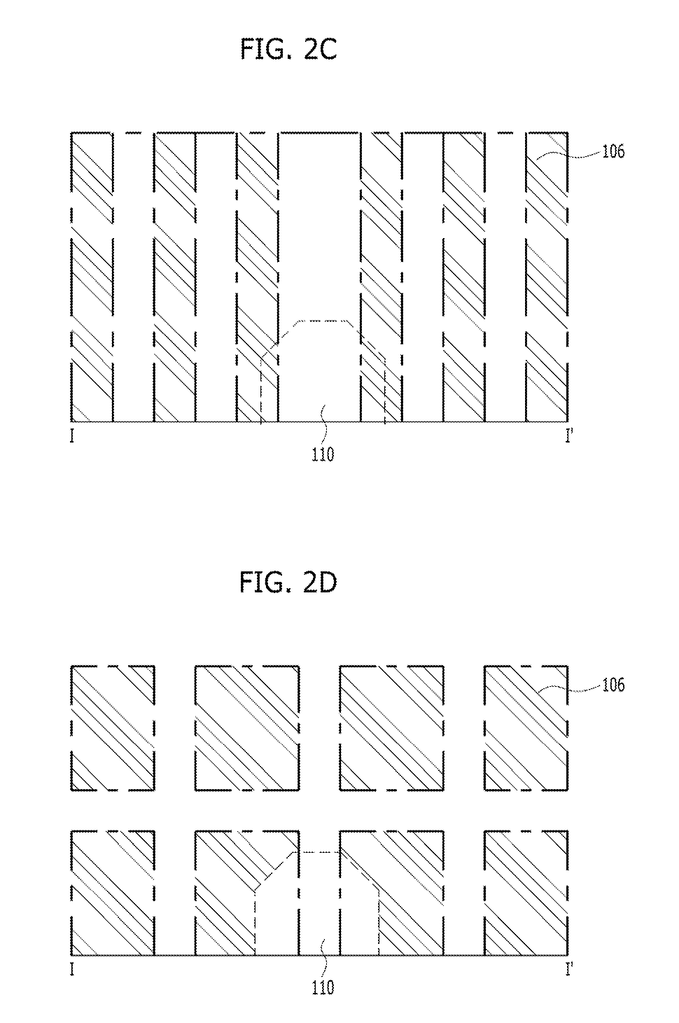

FIGS. 1A and 18 are diagrams illustrating a high voltage isolated transistor in accordance with an embodiment of the present invention. FIG. 1A is a plan view illustrating the high voltage isolated transistor, and FIG. 18 is a cross-sectional view of the high voltage isolated transistor taken along I-I′ line of FIG. 1A. FIGS. 2A to 2D are plan views illustrating modifications of a third buried impurity region in accordance with an embodiment of the present invention. For reference, a parasitic device of the high voltage isolated transistor according to an exemplary embodiment of the present invention, such as a parasitic bipolar NPN transistor, is shown in FIG. 18.

Referring to FIGS. 1A and 1B, the high voltage isolated transistor includes a substrate, an isolation region, a third buried impurity region, and a transistor.

The substrate includes a supporting substrate 101, first epitaxial layer 102 and a second epitaxial layer 103 stacked sequentially. The isolation region includes a first buried impurity region 104 formed from the supporting substrate 101 to the first epitaxial layer 102 and a second buried impurity region 105 formed from the first epitaxial layer 102 and the second epitaxial layer 103 and in contact with an edge of the first buried impurity region 104. The third buried impurity region 106 is formed from the first epitaxial layer 102 to the second epitaxial layer 103, is located in the second buried impurity region 105, and is overlapped with the first buried impurity region 104. The transistor is formed over the second epitaxial layer 103 and is overlapped with the third buried impurity region 106. Hereinafter, components of the high voltage isolated transistor will be described.

The high voltage isolated transistor may include the substrate having a plurality of epitaxial layers stacked over the supporting substrate 101. That is, the substrate may have a structure including the supporting substrate 101 of a first conductivity type, the first epitaxial layer 102 of the first conductivity type and the second epitaxial layer 103 of the first conductivity type sequentially stacked. The supporting substrate 101, the first epitaxial layer 102, and the second epitaxial layer 103 may be semiconductor layers. The semiconductor layer may be a single crystal state, and it may include a material containing silicon. That is, the semiconductor layer may include a material having single crystal silicon. For example, the supporting substrate 101 may be a bulk silicon substrate, and the first epitaxial layer 102 and the second epitaxial layer 103 may be silicon epitaxial layers. The first epitaxial layer 102 and the second epitaxial layer 103 perform the role of increasing the breakdown voltage by providing a sufficient thickness depletion region of high voltage isolated transistors, to be extended vertically.

The thickness and the impurity doping concentration of the first epitaxial layer 102 and the second epitaxial layer 103 may be the same or different. They may be controlled according to the breakdown voltage characteristics and a required specific on-resistance. For example, the breakdown voltage of the high voltage isolated transistor may be improved when the thickness of the first epitaxial layer 102 or/and the second epitaxial layer 103 is increased, or when the impurity doping concentration of the first epitaxial layer 102 is increased higher than that of the second epitaxial layer 103.

Additionally, the high voltage isolated transistor may include a transistor formed in the second epitaxial layer 103, e.g., a lateral double diffused MOSFET (LDMOS). The transistor includes a first deep well 107, a gate G, a body region 110, a drift region 112, a buried insulation layer 111, a source region 115, and a drain region 116.

The first deep well 107 of the first conductivity type is formed in the second epitaxial layer 103. The gate G is formed over the first deep well 107 of the second epitaxial layer 103. The body region 110 of the first conductivity type and the drift region 112 of the second conductivity type are formed in the first deep well 107, and are partially overlapped with the gate G. The buried insulation layer 111 is formed in the first deep well 107 including the drift region 112, and is partially overlapped with the gate G. The source region 115 of the second conductivity type is formed in the body region 110 and aligned with one end of the gate G. The drain region 116 of the second conductivity type is formed in the drift region 112 and is apart by a predetermined distance from other end of the gate G.

The first deep well 107 may be a base in the high voltage isolated transistor. The first deep well 107 may have a flat panel shape. The gate G is a stacked structure having a gate insulation layer and a gate electrode, and may be a ring shape surrounding the body region 110. In this embodiment, a planar type gate G is shown, but the gate G may have a 3D structure such as a recess type. The body region 110 provides a channel of the high voltage isolated transistor. The body region 110 may be formed in a center area of the high voltage isolated transistor, and the body region 110 may have a flat panel shape. The drift region 112 provides a stable current path between the source region 115 and the drain region 116. The drift region 112 may be arranged symmetrically on both sides of the body region 110 in any one direction, and have a flat panel shape, In a horizontal direction, the drift region 112 may be in contact with the body region 110, or may be apart from the body region 110 by a predetermined distance. The buried insulation layer 111 may be formed by a shallow trench isolation (STI) process. The source region 115 may have a ring shape, and a body pickup region 117 of the first conductivity type may be located in the source region 115. That is, the source region 115 may surround the body pickup region 117. In the horizontal direction, the source region 115 and the body pickup region 117 may be in contact with each other. The drain region 116 may be arranged symmetrically on both sides of the body region 110 in any one direction.

Additionally, the high voltage isolated transistor includes the third buried impurity region 106 of the first conductivity type formed under the first deep well 107 and formed from the first epitaxial layer 102 to the second epitaxial layer 103, a third deep well 109 of the first conductivity type formed in the second epitaxial layer 103 surrounding the first deep well 107 and being in contact with an edge of the third buried impurity region 106, a second well 114 of the first conductivity type formed in the third deep well 109, and a second pickup region 119 of the first conductivity type formed in the second well 114.

The third buried impurity region 106 increases the breakdown voltage of the high voltage isolated transistor by alleviating the electric field of the drain region 116. As the impurity doping concentration of the third buried impurity region 106 is increased, the breakdown voltage characteristics may be improved. The breakdown voltage characteristic may be further improved as the third buried impurity region 106 may be expanded outwardly to the drain region 116 in the horizontal direction. The third buried impurity region 106 may act as a parasitic device of the high voltage isolated transistor, for example, the third buried impurity region 106 may act as a base of a parasitic bipolar transistor. Thus, it is advantageously possible to suppress the operation of the parasitic device and further improve the breakdown voltage characteristics by adjusting the doping profile of the third buried impurity region 106. The third buried impurity region 106 may be overlapped with the first deep well 107, and may have a flat panel shape. The third buried impurity region 106 may have a larger area than the first deep well 107. The first deep well 107 and the third buried impurity region 106 may be in contact with each other in a vertical direction.

The third deep well 109 may have a ring shape surrounding the first deep well 107. The third deep well 109 may be in contact with the first deep well 107 in the horizontal direction, and the third deep well 109 may be in contact with the third buried impurity region 106 in the vertical direction. The third deep well 109, the second well 114 and the second pickup region 119 may provide bias to the third buried impurity region 106 through the electrical connection penetrating the second epitaxial layer 103. The second pickup region 119 is separated from the adjacent drain region 116 and the adjacent first pickup region 118 by the buried insulation layer 111.

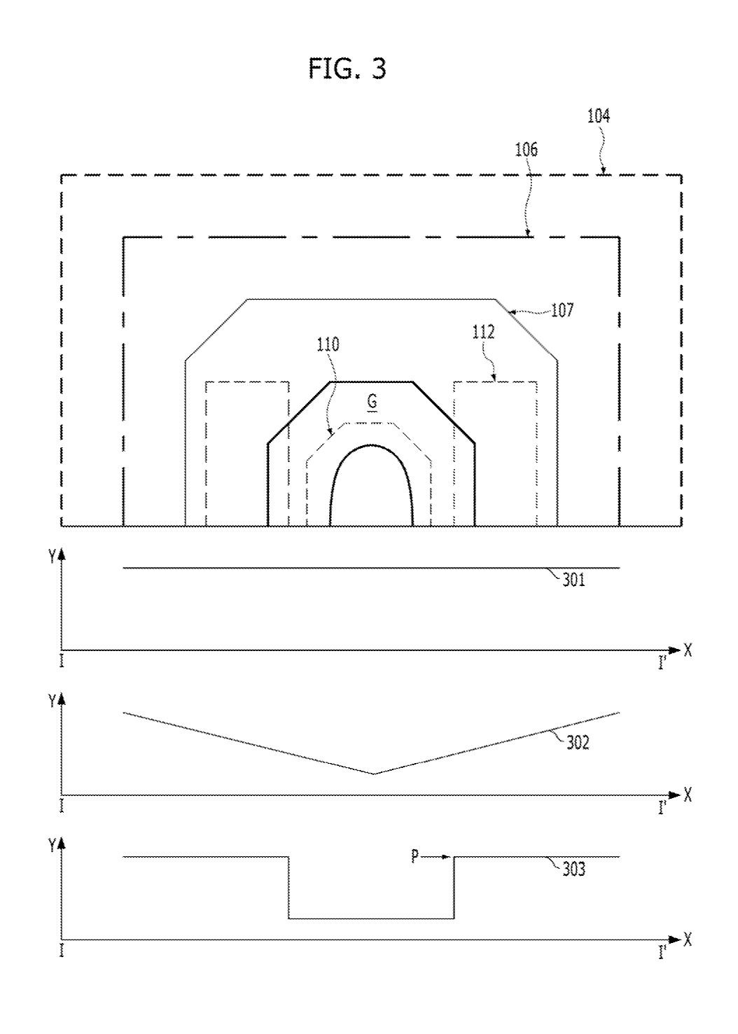

To improve the breakdown voltage characteristics of the high voltage isolated transistor by suppressing the operation of the parasitic devices, the doping profile of the third buried impurity region 106 may be adjusted. This will be described below in detail with reference to FIG. 3.

In this embodiment, the third buried impurity region 106 having the flat panel shape is described. However, the third buried impurity region 106 may have various shapes that effectively suppress the electric field of the high voltage isolated transistor as shown in FIGS. 2A to 2D.

Referring to FIG. 2A, the third buried impurity region 106 may have a fiat panel shape including a hole, or a ring shape. That is, the hole is formed in the region corresponding to the body region 110 in the third buried impurity region 106. The third buried impurity region 106 and the body region 110 may not be overlapped.

Referring to FIG. 2B, the third buried impurity region 106 may have a concentric circular shape including a central ring which may overlap the edge of the body region 110.

Referring to FIG. 2C, the third buried impurity region 106 may have a slit shape having a plurality of lines and a plurality of spacers. The slit shape may have many variations in form that extends in an oblique direction or a shape intersecting the form, which is shown in FIG. 2C.

Referring to FIG. 2D, the third buried impurity region 106 may have a shape having a plurality of polygons, e.g., squares, which are regularly arranged. The third buried impurity region 106 may have a checkered shape when the shape having the regularly arranged plurality of polygons is inverted.

The buried impurity region 106 shown in FIGS. 2A to 2D is isolated, but the third buried impurity region 106 is electrically connected by a connection element (not illustrated) of the first conductivity type having an impurity doping concentration lower than that of the third buried impurity region 106.

The high voltage isolated transistor may include an isolation region. As illustrated in FIGS. 1A and 1B, the isolation region may include the first buried impurity region 104 of the second conductivity type formed under the third buried impurity region 106 and formed from the supporting substrate 101 to the first epitaxial layer 102, the second buried impurity region 105 of the second conductivity type formed from the first epitaxial layer 102 to the second epitaxial layer 103 and is in contact with the edge of the first buried impurity region 104, a second deep well 108 of the second conductivity type formed in the second epitaxial layer 103 and is in contact with the second buried impurity region 105, a first well 113 of the second conductivity type formed in the second deep well 108, and the first pickup region 118 of the second conductivity type formed in the first well 113.

The first buried impurity region 104 suppresses the operation of the parasitic device by acting as the isolation region of the high voltage isolated transistor. The first buried impurity region 104 and the third buried impurity region 106 may overlap each other. The first buried impurity region 104 may be in contact with the third buried impurity region 106 and the first buried impurity region 104 may have a flat panel shape. The first buried impurity region 104 may have a larger area than the third buried impurity region 106.

The second buried impurity region 105 acts as the isolation region of the high voltage isolated transistor and the first buried impurity region 104. In the substrate structure having a plurality of epitaxial layers, the second buried impurity region 105 may provide an electrical connection way being able to apply a bias to the first buried impurity region 104 in the vertical direction. The second buried impurity region 105 may be in contact with the edge of the first buried impurity region 104 in the vertical direction. The second buried impurity region 105 is formed a predetermined distance away from the third buried impurity region 106 located inwardly in the horizontal direction, and thus the second buried impurity region 105 may have a ring shape surrounding the third buried impurity region 106. To prevent decreasing of the breakdown voltage due to the parasitic device, the second buried impurity region 105 must be apart by the predetermined distance from the third buried impurity region 106. When the second buried impurity region 105 and the third buried impurity region 106 are in contact with each other, a current path of the parasitic bipolar transistor does not pass through the first buried impurity region 104. The current path is connected from the third buried impurity region 106 to the second buried impurity region 105. Thus, the breakdown voltage may suddenly be degraded.

The second deep well 108 may have a ring shape surrounding the third deep well 109, and the second deep well 108 may be in contact with the third deep well 109 in the horizontal direction. The second deep well 108 may be in contact with the second buried impurity region 105 in the vertical direction. The second deep well 108, the first well 113 and the first pickup region 118 may provide an electrical connection that may be able to apply a bias to the first buried impurity region 104 and the second buried impurity region 105. The substrate has a structure in which the epitaxial layers are stacked. Thus, it is possible to apply a bias to the first buried impurity region 104 by including a basic well structure and the second buried impurity region 105. That is, it is possible to provide the isolation region with excellent isolation characteristics from the sides and the bottom of the high voltage isolated transistor.

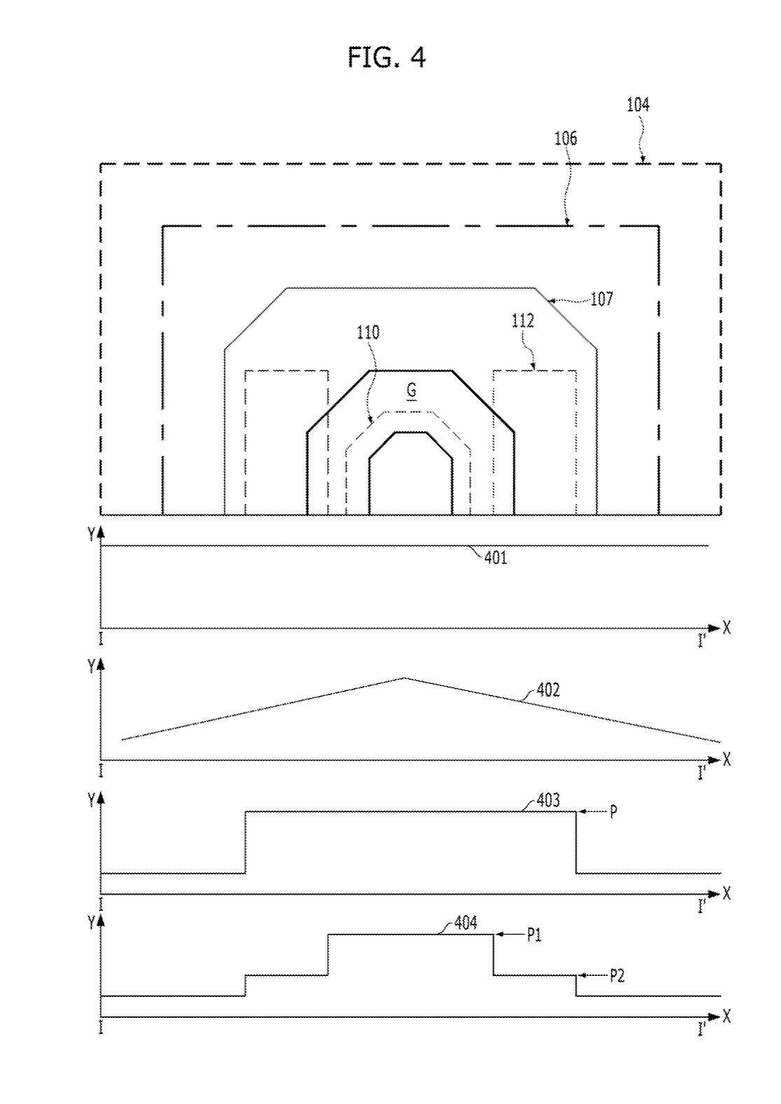

A doping profile may be adjusted to further improve the breakdown voltage characteristics of the high voltage isolated transistor by suppressing the operation of the parasitic device. This will be described in detail below with reference to FIG. 4.

According to an embodiment of the present invention described above, the breakdown voltage of the high voltage isolated transistor may be effectively improved by having the first buried impurity region 104, the second buried impurity region 105, the third buried impurity region 106 and the substrate structure with a plurality of epitaxial layers stacked over the support substrate 101.

Hereinafter, improvement of the breakdown voltage characteristics by adjusting the impurity doping profile of the first buried impurity region 104 and the third buried impurity region 106 will be described in detail with reference to FIGS. 3 and 4.

FIG. 3 is a diagram illustrating a doping profile of a third buried impurity region in accordance with an embodiment of the present invention. An X axis represents a horizontal position of the third buried impurity region 106, and a Y axis represents the impurity doping concentration of the center of the third buried impurity region 106.

Referring to FIGS. 1A, 1B and 3, when the third buried impurity region 106 of the present invention has the flat panel shape, the impurity doping concentration 301 of the third buried impurity region 106 is constant regardless of the position in the horizontal direction as shown in FIG. 3A. Additionally, the impurity doping concentrations 302 and 303 of the third buried impurity region 106 may increase as it goes in an outward direction from the body region 110. That is, the impurity doping concentrations 302 and 303 of the third buried impurity region 106 increase as they go from the body region 110 to the drain region 116.

Referring to FIG. 3, the third buried impurity region 106 corresponding to the center of the body region 110 has the lowest impurity doping concentration 302, and the doping profile of the third buried impurity region 106 may increase linearly as it goes in an outward direction from the body region 110. It is possible to suppress the operation of the parasitic device since the impurity doping concentration of the third buried impurity region 106 corresponding to the drain region 116 is relatively increased. That is, the doping concentration 302 may increase the breakdown voltage more than the doping concentration 301.

Specific on-resistance may be decreased since the third buried impurity region 106 corresponding to the body region 110 has relatively low impurity doping concentration and the impurity doping concentration of the first deep well 107 corresponding to the body region 110 is relatively increased.

Referring to FIG. 3, the third buried impurity region 106 corresponding to the body region 110 has relatively low impurity doping concentration 303 and the third buried impurity region 106 may have a stepped doping profile increasing outwardly from the body region 110. In the doping concentration 303, it is possible to suppress the operation of the parasitic device and the specific on-resistance may be decreased, as well as in the doping concentration 302.

A point P that represents the impurity doping concentration 303 of the third buried impurity region 106, changes abruptly. The point P may be arranged at the end of the drift region 112 below the gate G. In this instance, the breakdown voltage may be increased, and the specific on-resistance may be effectively decreased more than in doping concentrations 301 and 302.

FIG. 4 is a diagram illustrating a doping profile of a first buried impurity region in accordance with an embodiment of the present invention. The X axis represents the horizontal position of the first buried impurity region 104, and the Y axis represents the impurity doping concentration of the center of the first buried impurity region 104.

Referring to FIGS. 1A, 1B and 4, when the first buried impurity region 104 of the present invention has the flat panel shape, the impurity doping concentration 401 of the first buried impurity region 104 is constant regardless of the position in the horizontal direction. Additionally, the impurity doping concentration of the first buried impurity region 104 may decrease as it goes in an outward direction from the body region 110. That is, the impurity doping concentrations 402, 403, 404 of the first buried impurity region 104 decrease as they go from the body region 110 to the drain region 116.

The first buried impurity region 104 corresponding to the center of the body region 110 has the highest impurity doping concentration 402, and the doping profile of the first buried impurity region 104 may decrease linearly as it goes in an outward direction from the body region 110. In this instance, the impurity doping concentration 402 of the third buried impurity region 106 corresponding to the drain region 116 is relatively increased since the impurity doping concentration of the first buried impurity region 104 corresponding to the drain region 116 is relatively low. Thus, the doping concentration 402 increases the breakdown voltage more than the doping concentration 401, by suppressing the operation of the parasitic devices.

When the doping concentrations 403 and 404 are utilized, the first buried impurity region 104 corresponding to the body region 110 has relatively high impurity doping concentration, and the first buried impurity region 104 may have a stepped doping profile decreasing outwardly from the body region 110. Therefore, it is possible to suppress the operation of the parasitic device as well as in doping concentration 402.

When the doping concentration 403 is utilized, a point P that represents the impurity doping concentration of the first buried impurity region 104, changes abruptly. The point P may be arranged at the end of the drift region 112 so that is not overlapped with the gate G. Additionally, when the doping concentration 404 is utilized, points P1 and P2 represent that the impurity doping concentration of the first buried impurity region 104, changes abruptly. The point P1 may be arranged at one end of the drift region 112 below the gate G, and the point P2 may be arranged at the other end of the drift region 112 below the gate G. In doping concentrations 403 and 404, the breakdown voltage may be increased more than when using the doping concentrations 401 and 402.

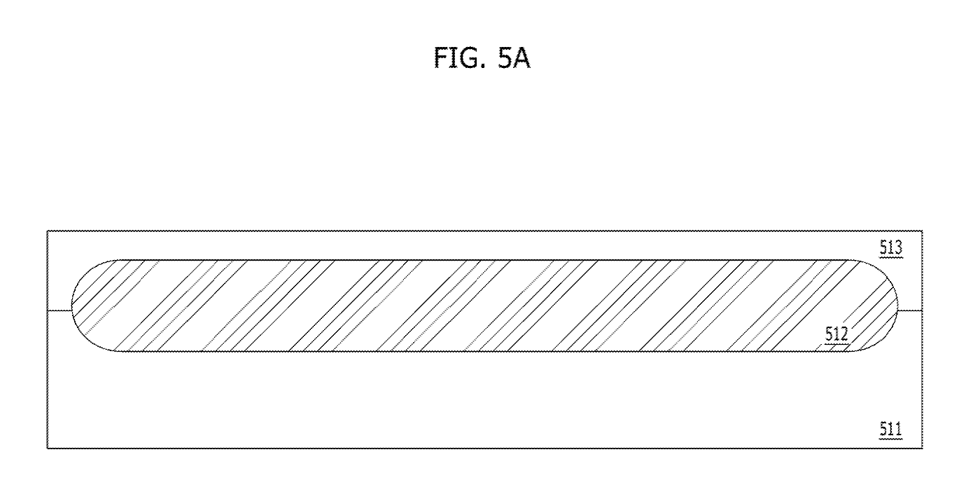

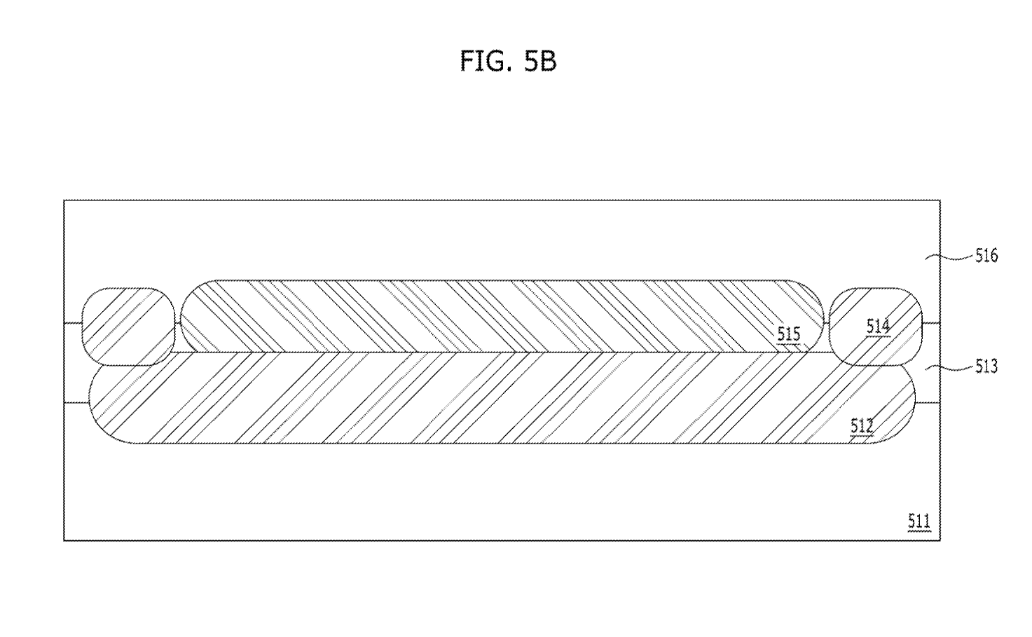

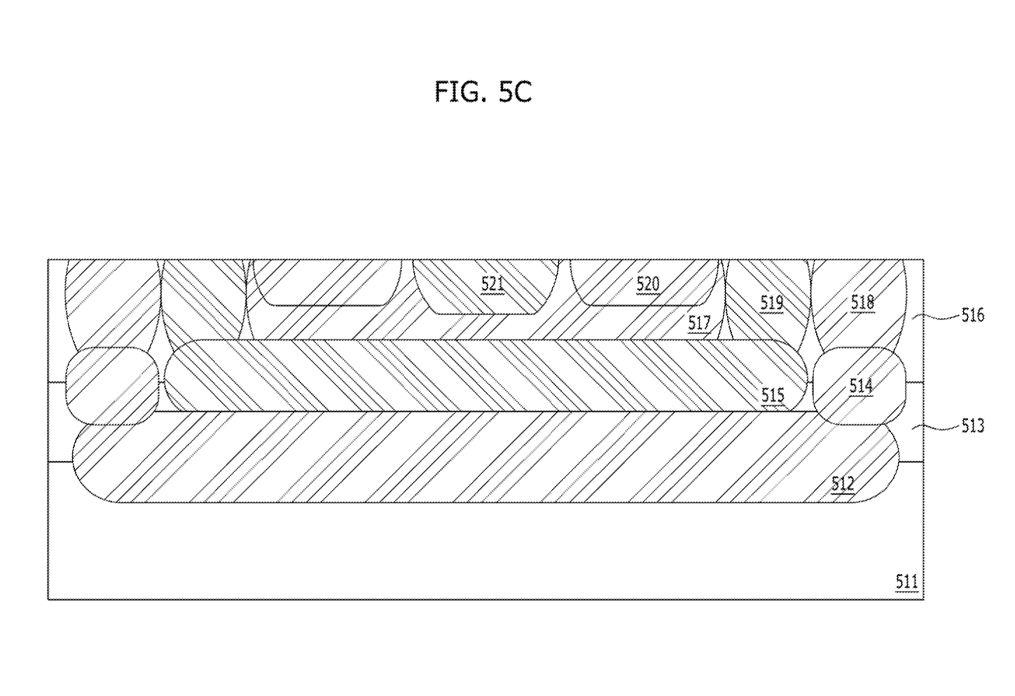

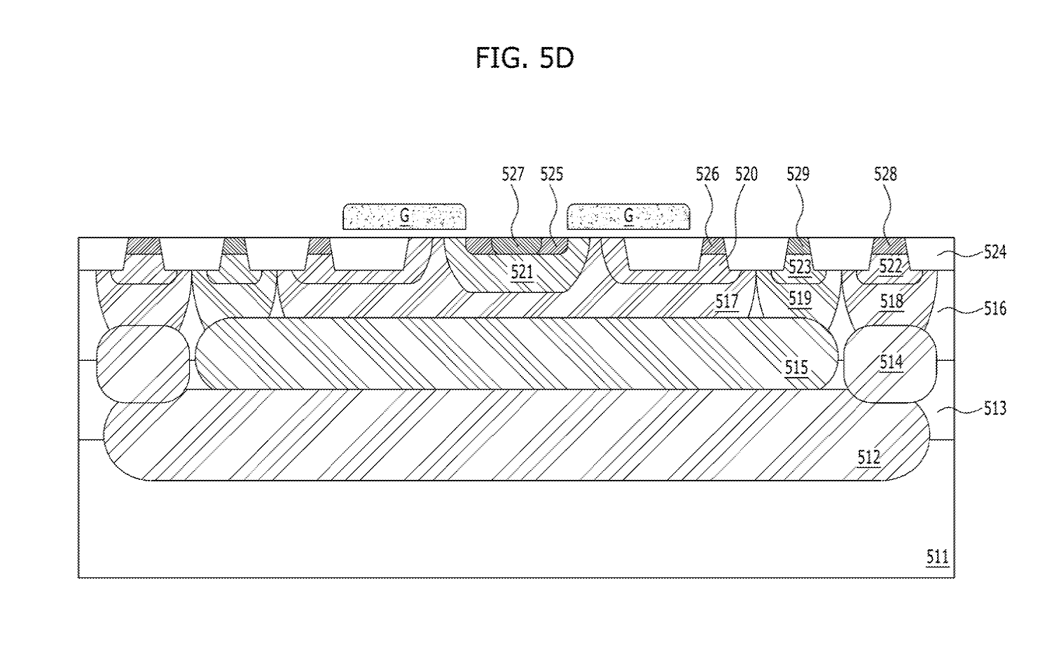

Hereinafter, a method for fabricating a semiconductor device in accordance with an embodiment having the structure shown in FIGS. 1A and 1B will be described with reference to FIGS. 5A to 5D.

FIGS. 5A to 5D are cross-sectional views illustrating a method for fabricating a semiconductor device in accordance with an embodiment of the present invention taken along line of FIG. 1A.

Referring to FIG. 5A, a supporting substrate 511 of a first conductivity type is prepared. The supporting structure 511 may be a semiconductor substrate. The semiconductor substrate may be a single crystal state, and it may include a material containing silicon. That is, the semiconductor substrate may include a material having single crystal silicon. For example, the supporting substrate 511 may be a P-type bulk silicon substrate.

Subsequently, a first impurity of a second conductivity type is implanted into the supporting substrate 511 by using a first mask pattern (not illustrated) formed over the supporting substrate 511 as an ion implant barrier. That is, one or more N-type impurity may be implanted into the supporting substrate 511. The N-type impurity may include phosphorus (P), arsenic (As) and antimony (Sb).

Subsequently, a first epitaxial layer 513 of the first conductivity type is formed over the supporting substrate 511. The impurity doping concentration of the first epitaxial layer 513 may be higher than that of the supporting substrate 511. The first epitaxial layer 513 may be formed using an epitaxial growth, and the first epitaxial layer 513 may include a material containing silicon. While the first epitaxial layer 513 is formed, P-type impurity may be doped into the first epitaxial layer 513 by injecting the P-type impurity into a chamber in-situ. The P-type impurity may include boron (B). For example, the first epitaxial layer 513 may be a P-type silicon epitaxial layer.

Since the first impurity of the second conductivity type implanted into the supporting substrate 511 is activated by activation energy such as thermal energy provided during the formation of the first epitaxial layer 513, a first buried impurity region 512 of the second conductivity type may be formed simultaneously. The first buried impurity region 512 may have a flat panel shape. The first buried impurity region 512 may have a constant impurity doping concentration, or the impurity doping concentration of the first buried impurity region 512 is decreased from the center to the outside portion of the first buried impurity region 512.

Before forming of the first epitaxial layer 513 or after forming of the first epitaxial layer 513, a separate annealing process to form the first buried impurity region 512 may be performed. The annealing process may be performed in a furnace.

Referring to FIG. 5B, a second impurity of the second conductivity type is implanted into the first epitaxial layer 513 corresponding to edge of the first buried impurity region 512 by using a second mask pattern (not illustrated) formed over the first epitaxial layer 513 as an ion implant barrier.

Subsequently, a third impurity of the first conductivity type is implanted into the first epitaxial layer 513 corresponding to the first buried impurity region 512 removing the edge of the first buried impurity region 512 by using a third mask pattern (not illustrated) formed over the first epitaxial layer 513 as an ion implant barrier.

Thereafter, a second epitaxial layer 516 of the first conductivity type is formed over the first epitaxial layer 513. The impurity doping concentration of the second epitaxial layer 512 may be the same or lower than that of the first epitaxial layer 511

The second epitaxial layer 516 may be formed using an epitaxial growth, and the second epitaxial layer 516 may include a material containing silicon. While the second epitaxial layer 516 is formed, the impurity of the first conductivity type, i.e., P-type impurity, may be doped into the second epitaxial layer 516 by injecting the P-type impurity into a chamber in-situ. For example, the second epitaxial layer 516 may be a P-type silicon epitaxial layer.

Since the second impurity of the second conductivity type and the third impurity of the first conductivity type implanted into the first epitaxial layer 513 are activated by a thermal energy provided during the formation of the second epitaxial layer 516, a second buried impurity region 514 of the second conductivity type and a third buried impurity region 515 of the first conductivity type may be formed, respectively. The area of the third buried impurity region 515 may be smaller than that of the first buried impurity region 512. The third buried impurity region 515 may have a constant impurity doping concentration, or the impurity doping concentration of the third buried impurity region 515 is increased from the center to the outside portion of the third buried impurity region 515. The second buried impurity region 514 may be apart from the third buried impurity region 515 by a predetermined distance, and may have a ring shape surrounding the third buried impurity region 515. The second buried impurity region 514 may be in contact with the edge of the first buried impurity region 512.

Before forming the second epitaxial layer 516 or forming the second epitaxial layer 516, a separate annealing process to form the second buried impurity region 514 and the third buried impurity region 515 may be performed. The annealing process may be performed in a furnace.

Referring to FIG. 5C, a fourth impurity of the second conductivity type is implanted into the second epitaxial layer 516 corresponding to the second buried impurity region 514 and the third buried impurity region 515, then removing the edge of the third buried impurity region 515 by using a fourth mask pattern (not illustrated) formed over the second epitaxial layer 516 as an ion implant barrier.

Subsequently, a fifth impurity of the first conductivity type is implanted into the second epitaxial layer 515 corresponding to edge of the third buried impurity region 515 by using a fifth mask pattern (not illustrated) formed over the second epitaxial layer 516 as an ion implant barrier.

An annealing process is performed to activate the first conductivity type impurity and the second conductivity type impurity implanted into the second epitaxial layer 516. The annealing process may be performed in a furnace.

Therefore, a first deep well 517 of the second conductivity type, a second deep well 518 of the second conductivity type, and a third deep well 519 of the first conductivity type may be formed in the second epitaxial layer 516.

The first deep well 517 may have a flat panel shape and may be overlapped with the third buried impurity region 515 excepting the edge of the third buried impurity region 515. The area of the first deep well 517 is smaller than that of the third buried impurity region 515. The second deep well 518 is in contact with the second buried impurity region 514, and may have a ring shape surrounding the first deep well 517 and the third deep well 519. The third deep well 519 may have a ring shape surrounding the first deep well 517.

Subsequently, a sixth impurity of the second conductivity type is implanted into both sides of the first deep well 517 in one direction by using a sixth mask pattern (not illustrated) formed over the second epitaxial layer 516 as an ion implant barrier. An annealing process is performed to activate the implanted impurity into the first deep well 517. The annealing process may be performed in a furnace. As a result, a drift region 520 of the second conductivity type may be formed in the first deep well 517. The drift region 520 may have a flat panel shape.

Subsequently, a seventh impurity of the first conductivity type is implanted into the center of the first deep well 517 by using a seventh mask pattern (not illustrated) formed over the second epitaxial layer 516 as an ion implant barrier. An annealing process is performed to activate the implanted impurity into the first deep well 517. The annealing process may include a rapid thermal process. As a result, a body region 521 of the first conductivity type may be formed in the first deep well 517. The drift region 520 may be placed on both sides of the body region 521. The body region 521 may have a flat panel shape.

Referring to FIG. 5D, a plurality of buried insulation layers 524 are formed in the second epitaxial layer 516. The buried insulation layers 524 may be formed by using a shallow trench isolation (STI) process. In the STI process, a trench is formed and the trench is filled with an insulation material. Part of the plurality of buried insulation layers 524 may be formed along a boundary where the first to third deep wells 517 to 519 are in contact with each other. The remainder of the plurality of buried insulation layers 524 may be formed in the first deep well 517 including the drift region 520.

Subsequently, a first well 522 of the second conductivity type is formed in the second deep well 519, and a second well 523 of the first conductivity type is formed in the third deep well 519. The first well 522 and the second well 523 may be formed by performing an ion implantation process and an annealing process in sequence.

Thereafter, a gate G is formed over the second epitaxial layer 516. The gate G may be formed of a stacked structure in which a gate insulation layer and a gate electrode are sequentially stacked. The gate G may be partially overlapped with the body region 521, the drift region 520 and the buried insulation layers 524.

Subsequently, a source region 525, a drain region 526 and a first pickup region 528 of the second conductivity type, and a body pickup region 527 and a second pickup region 529 of the first conductivity type, are formed. They may be formed by performing an ion implantation process and an annealing process in sequence.

In the method for forming the isolation region of the high voltage isolated transistor, even when the substrate having a plurality of epitaxial layer is used for increasing the breakdown voltage, it is possible to provide the isolation region with excellent isolation characteristics from the sides and bottom of the high voltage isolated transistor by forming a buried impurity region such as the second buried impurity region 514, when the epitaxial layer is formed.

According to an embodiment of the present invention, it is possible to increase the breakdown voltage by providing a sufficient thickness depletion region of the transistor to be extended since the semiconductor device is formed in the substrate having a plurality of epitaxial layers.

Also, according to an embodiment of the present invention, the breakdown voltage may be increased by alleviating the electric filed of the transistor since the third buried impurity region is formed under the transistor. The third buried impurity region may increase the breakdown voltage by suppressing the operation of the parasitic device.

Furthermore, even when the substrate having a plurality of epitaxial layer is used, an isolation region having excellent isolation characteristics may be provided due to the second buried impurity region. The second buried impurity region may increase the breakdown voltage by suppressing the operation of the parasitic device.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a substrate having a supporting substrate, wherein a first epitaxial layer and a second epitaxial are sequentially stacked;
an isolation region including a first buried impurity region of a second conductivity type and a second buried impurity region of the second conductivity type, wherein the first buried impurity region is formed from the supporting substrate to the first epitaxial layer, and the second buried impurity region is formed from the first epitaxial layer to the second epitaxial layer and is in contact with an edge of the first buried impurity region;
a third buried impurity region of a first conductivity type formed from the first epitaxial layer to the second epitaxial layer, located in the second buried impurity region and overlapped with the first buried impurity region; and
a transistor formed over the second epitaxial layer and overlapped with the third buried impurity region.

2. The semiconductor device of claim 1, wherein the third buried impurity region includes a shape selected from a group including a flat panel shape, a ring shape, a concentric circular shape, a slit shape, a shape having a plurality of polygons and a checkered shape.

3. The semiconductor device of claim 1, wherein the second buried impurity region has a ring shape surrounding the third buried impurity region, and the second buried impurity region is arranged apart from the third buried impurity region by a predetermined distance.

4. The semiconductor device of claim 1, wherein the first buried impurity region has a larger area than the third buried impurity region.

5. The semiconductor device of claim 1, wherein the first conductivity type is complementary to the second conductivity type.

6. A semiconductor device, comprising:
a substrate having a supporting substrate, wherein a first epitaxial layer and a second epitaxial are sequentially stacked;
a transistor including a body region of a first conductivity, a drift region of a second conductivity and a gate, wherein the body region is formed over the second epitaxial layer, wherein the drift region is formed over the second epitaxial layer and at both sides of the body region, and the gate is partially overlapped with the body region and the drift region;
a third buried impurity region of the first conductivity type formed from the first epitaxial layer to the second epitaxial layer, and formed under the body region and the drift region; and
an isolation region including a first buried impurity region of the second conductivity type and a second buried impurity region of the second conductivity type, wherein the first buried impurity region wraps a bottom of a structure including the body region and the drift region and the third buried impurity region, and the second buried impurity region surrounds a side of the structure.

7. The semiconductor device of claim 6, wherein the body region and the drift region have a flat panel shape and the drift region is arranged symmetrically relative to the body region.

8. The semiconductor device of claim 6, wherein the third buried impurity region includes a shape selected from a group including a flat panel shape, a ring shape, a concentric circular shape, a slit shape, a shape having a plurality of polygons and a checkered shape.

9. The semiconductor device of claim 6, wherein the third buried impurity region has a doping profile, wherein the doping profile has the lowest impurity doping concentration at a portion of the third buried impurity region corresponding to the body region and increases linearly as it goes an outward direction from the body region.

10. The semiconductor device of claim 6, wherein the third buried impurity region has a stepped doping profile, wherein the stepped doping profile includes a higher impurity doping concentration at a portion of the third buried impurity region corresponding to the drift region than that of a portion of the third buried impurity region corresponding to the body region.

11. The semiconductor device of claim 10, wherein a point that the impurity doping concentration of the third buried impurity region is changed, is arranged at the end of the drift region below the gate.

12. The semiconductor device of claim 6, wherein the first buried impurity region is formed from the supporting substrate to the first epitaxial layer and formed under the third buried impurity region.

13. The semiconductor device of claim 6, wherein the first buried impurity region has a larger area than the third buried impurity region.

14. The semiconductor device of claim 6, wherein the first buried impurity region has a doping profile, wherein the doping profile has the highest impurity doping concentration at a portion of the first buried impurity region corresponding to the body region and decreases linearly as it goes an outward direction from the body region.

15. The semiconductor device of claim 6, wherein the first buried impurity region has a stepped doping profile, wherein the stepped doping profile includes the highest impurity doping concentration at a portion of the first buried impurity region corresponding to the body region and decreases outwardly from the body region.

16. The semiconductor device of claim 15 wherein a point that the impurity doping concentration of the first buried impurity region is changed, is arranged at an end of the drift region that is not overlapped with the gate, or points that the impurity doping concentration of the first buried impurity region are changed, are arranged at one end of the drift region below the gate and at the other end of the drift region that is not overlapped with the gate.

17. The semiconductor device of claim 6, wherein the second buried impurity region is formed from the first epitaxial layer and the second epitaxial layer and is in contact with an edge of the first buried impurity region.

18. The semiconductor device of claim 6, wherein the second buried impurity region has a ring shape surrounding the third buried impurity region, and the second buried impurity region is arranged apart from the third buried impurity region by a predetermined distance.

19. The semiconductor device of claim 6, wherein the first conductivity type is complementary to the second conductivity type.
